(19) United States
(12) Patent Application Publication
(10) Pub. No.: US 2026/0056250 A1
(43) Pub. Date: Feb. 26, 2026

(54) AUTOMATED BURN-IN TEST SYSTEM

(71) Applicant: King Yuan Electronics Co., Ltd., Hsin-Chu (TW)

(72) Inventors: Chan-Yu WU, Hsin-Chu (TW); Teng Da HUANG, Hsin-Chu (TW); Po-Hsun LEE, Hsin-Chu (TW); Hsung Liang CHANG, Hsin-Chu (TW)

(21) Appl. No.: 19/260,642

(22) Filed: Jul. 7, 2025

(30) Foreign Application Priority Data
Aug. 21, 2024 (TW) 113131474

(51) Int. Cl. G01R 31/28

(52) U.S. Cl. CPC G01R 31/2863; G01R 31/2867

(57) ABSTRACT

An automated burn-in test system includes a plurality of burn-in test furnaces, a tray storage device and a plurality of sorting machines. The tray storage device is arranged on one side of the burn-in test furnaces to store a plurality of trays for accommodating a plurality of chips, and the sorting machines are disposed between the burn-in test furnaces and the tray storage device to exchange chips between the trays and a plurality of carriers.

### RELATED APPLICATIONS

This application claims priority to Taiwan Application Serial Number 113131474, filed Aug. 21, 2024, the disclosures of which are incorporated herein by reference in their entireties.

### TECHNICAL FIELD

The present disclosure relates to a burn-in test system. More particularly, the present disclosure relates to an automated burn-in test system.

### BACKGROUND

With the advancement of technology, electronic products have become more popular, and gradually changed the life or work of many people. Therefore, the function and calculating power of the chips are gradually increased.

In order to ensure that high-performance chips can work properly and to screen out normal chips and exclude defective chips during the manufacturing process, semiconductor factories will conduct reliability tests after completing chip production. In current testing methods, the chips are subjected to environmental tests, such as operational life tests (OLTs).

The testing method is to place the chips into a high-temperature furnace and input some control signals into the chips to simulate a condition under which the chips execute these control signals in a high-temperature environment. The purpose is to find defective products through these testing processes during the manufacturing process to ensure that each manufactured chip can work normally as designed.

However, since the high-power burn-in chips have to be frequently to picked and placed, and the size and weight of the burn-in board are greatly increased, a large amount of manpower is still required to operate so as to result in low efficiency and more safety risks.

Therefore, there is a need to effectively improve the efficiency and accuracy of the burn-in test so as to improve the reliability and service life of chips and electronic devices.

### SUMMARY

The summary of the present invention is intended to provide a simplified description of the disclosure to enable readers to have a basic understanding of the disclosure. The summary of the present invention is not a complete overview of the disclosure, and it is not intended to point out the importance of the embodiments/key elements of the present invention or define the scope of the invention.

One objective of the embodiments of the present invention is to provide an automated burn-in test system to improve the efficiency of burn-in test of chips so as to effectively improve the quality of the chips.

To achieve these and other advantages and in accordance with the objective of the embodiments of the present invention, as the embodiment broadly describes herein, the embodiments of the present invention provides an automated burn-in test system including a plurality of burn-in test furnaces, a tray storage device and a plurality of sorting machines. The tray storage device is arranged on one side of the burn-in test furnaces to accommodate a plurality of trays for storing a plurality of chips. The sorting machines are arranged between the burn-in test furnaces and the tray storage device to exchange the chips between the trays and a plurality of carriers.

In some embodiments, each of the sorting machines includes an IC exchange unit to exchange the chips between the trays and the carriers.

In some embodiments, the automated burn-in test system further includes a tray automatic transport vehicle arranged between the tray storage device and the sorting machines to transfer the trays from the tray storage device to the sorting machines.

In some embodiments, the automated burn-in test system further includes a tray relay unit equipped between the sorting machines and the tray automatic transport vehicle to temporarily store the trays.

In some embodiments, the tray relay unit is a tray relay automatic transport vehicle to move between the sorting machines and the tray automatic transport vehicle and temporarily store the trays.

In some embodiments, the automated burn-in test system further includes a carrier storage rack arranged adjacent to the burn-in test furnaces and the sorting machines to store the carriers.

In some embodiments, the automated burn-in test system further includes a carrier automatic transport vehicle arranged between the carrier storage rack, the sorting machines and the burn-in test furnaces to move the carriers in the carrier storage rack, the sorting machines and the burn-in test furnaces.

In some embodiments, the automated burn-in test system further includes a burn-in test board storage device to store a plurality of burn-in test boards.

In some embodiments, the automated burn-in test system further includes a burn-in test board automatic transport vehicle arranged between the burn-in test board storage device and the burn-in test furnaces to transfer the burn-in test boards between the burn-in test board storage device and the burn-in test furnaces.

In some embodiments, each of the burn-in test furnaces includes a burn-in test board load and unload unit to dock with the burn-in test board automatic transport vehicle for loading or unloading the burn-in test boards.

In some embodiments, each of the burn-in test furnaces further includes an automatic pick and place unit to dock with the carrier automatic transport vehicle to load or unload the chips of the carriers to burn-in the chips or move the chips to the carriers after a burn-in test is finished.

In some embodiments, the automated burn-in test system further includes an input and output automatic transport vehicle arranged between the burn-in test board automatic transport vehicle, the burn-in test furnaces and the carrier automatic transport vehicle to load and unload the burn-in test boards and the chips of the carriers.

In some embodiments, the input and output automatic transport vehicle includes a burn-in test board load and unload unit to dock with the burn-in test board automatic transport vehicle to load or unload the burn-in test boards.

In some embodiments, the input and output automatic transport vehicle further includes an automatic pick and place unit to dock with the carrier automatic transport vehicle to load or unload the chips of the carriers to burn-in the chips or move the chips to the carriers after a burn-in test is finished.

In some embodiments, the automated burn-in test system further includes a tray relay automatic transport vehicle equipped between the sorting machines and the tray automatic transport vehicle to move between the sorting machines and the tray automatic transport vehicle and temporarily store the trays.

In some embodiments, wherein the sorting machines include a load relay device to move the chips to the carriers and an unload relay device to move the chips to the trays.

In some embodiments, the load relay device and the unload relay device respectively include an IC exchange unit to move the chips between the carriers and the trays.

In some embodiments, the automated burn-in test system further includes a first tray relay unit and a second tray relay unit. The first tray relay unit is equipped between the load relay device and the tray automatic transport vehicle to temporarily store the trays. In addition, the second tray relay unit is equipped between the unload relay device and the tray automatic transport vehicle to temporarily store the trays.

In some embodiments, the automated burn-in test system further includes a tray relay automatic transport vehicle equipped between the load relay device, the unload relay device and the tray automatic transport vehicle to move between the load relay device, the unload relay device and the tray automatic transport vehicle and temporarily store the trays.

In some embodiments, each of the burn-in test furnaces includes a burn-in test board load and unload unit to dock with a burn-in test board automatic transport vehicle to load or unload a plurality of burn-in test boards.

In some embodiments, each of the burn-in test further furnaces includes an automatic pick and place unit to dock with a carrier automatic transport vehicle to load or unload the chips of the carriers to burn-in the chips or move the chips to the carriers after a burn-in test is finished.

In some embodiments, the automated burn-in test system further includes an input and output automatic transport vehicle arranged between a burn-in test board automatic transport vehicle, the burn-in test furnaces and a carrier automatic transport vehicle to load or unload a plurality of burn-in test boards and the chips of the carriers.

In some embodiments, the input and output automatic transport vehicle includes a burn-in test board load and unload unit to dock with the burn-in test board automatic transport vehicle to load or unload the burn-in test boards.

In some embodiments, the input and output automatic transport vehicle further includes an automatic pick and place unit to dock with the carrier automatic transport vehicle to load or unload the chips of the carriers to burn-in the chips or move the chips to the carriers after a burn-in test is finished.

In some embodiments, the tray relay unit includes a tray storage unit and a tray moving unit. The tray storage unit is utilized to store the trays and the tray moving unit is arranged on one side of the tray storage unit to move the trays into or remove the trays from the tray storage unit.

In some embodiments, each of the sorting machines includes a tray distribution unit, an IC exchange unit and a carrier storage unit. The IC exchange unit exchanges the chips between the trays and the carriers, and the carrier storage unit is utilized to temporarily store the carriers.

In some embodiments, the IC exchange unit includes an IC rotating module, a tray locating device and a carrier locating device. The tray locating device is arranged on one side of the IC rotating module to position a tray. The carrier locating device is arranged on another side of the IC rotating module to position a carrier, wherein when directions of the chips of the tray are not correct, the IC exchange unit picks one of the chips to the IC rotating module and the IC rotating module rotates the one of the chips to a predetermined direction, and then the IC exchange unit picks the one of the chips to the carriers.

In some embodiments, the tray distribution unit includes a tray distribution module, and the tray distribution module includes a supporting wall, a rotatable rail, a rotatable supporting device and a tray picking device. The rotatable rail is rotatably mounted on the supporting wall, the rotatable supporting device is rotatably mounted on the supporting wall and located above the rotatable rail, and the tray picking device is movably mounted on the supporting wall.

In some embodiments, the tray distribution module further includes a shaft, an elastic device and a stopping block. The shaft is fixed on the supporting wall, and the rotatable rail is rotatably mounted on the shaft. The elastic device is connected between the rotatable rail and the supporting wall, and the stopping block is fixed on the supporting wall to limit a rotational angle of the rotatable rail.

In some embodiments, the tray picking device includes a moving unit, a first rotatable protrusion and a second rotatable protrusion. The moving unit is movably installed on the supporting wall, the first rotatable protrusion is rotatably installed on the moving unit, and the second rotatable protrusion is rotatably installed on the moving unit and located above the first rotatable protrusion.

In some embodiments, the tray distribution module further includes a lifting device installed under the tray picking device to lift the trays.

In some embodiments, each of the carriers includes a base plate, a plurality of positioning units, a baffle, a pushing piece and an elastic device. The base plate includes a plurality of IC seats to support a plurality of chips, the positioning units are fixed on the base plate, the baffle is installed on the base plate, the baffle includes a plurality of sliding slots and a plurality of openings, the sliding slots movably coupled to the positioning units, and the openings are disposed corresponding to the IC seats. The pushing piece is disposed on the base plate to move the baffle to expose the chips on the IC seats and the elastic device is connected between the pushing piece and the base plate to reset the baffle so as to cover a portion area of the chips of the IC seats to fix the chips on the IC seats.

Hence, the automated burn-in test system disclosed in the present invention may utilize the tray storage device, the sorting machines, the tray relay units and the tray automatic transport vehicle to effectively increase the exchange efficiency of the chips and the burn-in test efficiency so as to quickly provide the required chips for the burn-in test furnaces and reduce the number of transports by automated transport vehicles. In addition, the burn-in test furnaces may be equipped with the burn-in test board load and unload unit and the automatic pick and place unit, both of which are integrated into the burn-in furnace and suitable for chip testing with a short burn-in cycle. In addition, the burn-in test board automatic transport vehicle may be used in conjunction with the burn-in test board load and unload unit to automatically transport, install and unload burn-in test boards so as to effectively improve the installation efficiency of the burn-in test boards and further improve the testing efficiency of the chips. Furthermore, because the input and output automatic transport vehicle is equipped with the burn-in test board load and unload unit and the automatic pick and place unit, an one-to-many design is suitable for testing chips with a long burn-in cycle. In addition, the tray relay automatic transport vehicle and the tray automatic transport vehicle may further flexible adjust the trays and the chips of the tray relay automatic transport vehicle and the sorting machines so as to effectively reduce equipment costs. Furthermore, by way of the load relay device, the unload relay device, the tray relay units and the tray automatic transport vehicle, the automated burn-in test system may effectively increase the exchange efficiency of the chips so as to quickly provide the required chips for the burn-in test furnaces and reduce the number of transports by automated transport vehicles to further improve the quality of the chips.

### BRIEF DESCRIPTION OF THE DRAWINGS

The disclosure can be more fully understood by reading the following detailed description of the embodiment, with reference made to the accompanying drawings as follows:

FIG. 1 illustrates a schematic view of an automated burn-in test system according to a first embodiment of the present invention;

FIG. 2 illustrates a schematic view of an automated burn-in test system according to a second embodiment of the present invention;

FIG. 3 illustrates a schematic view of an automated burn-in test system according to a third embodiment of the present invention;

FIG. 4 illustrates a schematic view of an automated burn-in test system according to a fourth embodiment of the present invention;

FIG. 5 illustrates a schematic view of an automated burn-in test system according to a fifth embodiment of the present invention;

FIG. 6 illustrates a schematic view of an automated burn-in test system according to a sixth embodiment of the present invention;

FIG. 7 illustrates a schematic view of an automated burn-in test system according to a seventh embodiment of the present invention;

FIG. 8 illustrates a schematic view of an automated burn-in test system according to an eighth embodiment of the present invention;

FIG. 9 illustrates a side view of a sorting machine and a tray relay unit of an automated burn-in test system according to one embodiment of the present invention;

FIG. 10 illustrates a top view of a sorting machine and a carrier automatic transport vehicle of an automated burn-in test system according to one embodiment of the present invention;

FIG. 11 illustrates a schematic perspective view of a carrier of an automated burn-in test system according to one embodiment of the present invention;

FIG. 12A illustrates a side view of a tray distribution module of an automated burn-in test system according to one embodiment of the present invention;

FIG. 12B illustrates an enlarged partial view of a rotatable rail of a tray distribution module of an automated burn-in test system according to one embodiment of the present invention;

FIGS. 13A-13E illustrate working flow diagrams of a tray distribution module of an automated burn-in test system according to one embodiment of the present invention;

FIGS. 14A-14F illustrate another working flow diagrams of a tray distribution module of an automated burn-in test system according to one embodiment of the present invention; and

FIGS. 15A-15F illustrate further another working flow diagrams of a tray distribution module of an automated burn-in test system according to one embodiment of the present invention.

### DETAILED DESCRIPTION OF THE PREFERRED EMBODIMENT

The following is a detailed description of the embodiments in conjunction with the accompanying drawings, but the provided embodiments are not intended to limit the scope of the disclosure, and the description of the structure and operation is not used to limit the execution sequence thereof. The structure of the recombination of components and the resulting devices with equal functions are all within the scope of this disclosure. In addition, the drawings are for illustration purposes only, and are not drawn according to the original scale. For ease of understanding, the same reference numbers are used in the drawings and the description to refer to the same or like parts.

In addition, the terms used in the entire description and the scope of the patent application, unless otherwise specified, usually have the usual meaning of each term used in this field, in the content disclosed here and in the special content. Some terms used to describe the disclosure are discussed below or elsewhere in this specification to provide additional guidance to those skilled in the art in the disclosure.

In the implementation mode and the scope of the present application, unless the article is specifically limited in the context, “a” and “the” can generally refer to a single or pluralities. In the steps, the numbering is only used to conveniently describe the steps, rather than to limit the sequence and implementation.

Secondly, the words “comprising”, “including”, “having”, “containing” and the like used in the present application are all open language, meaning including but not limited to.

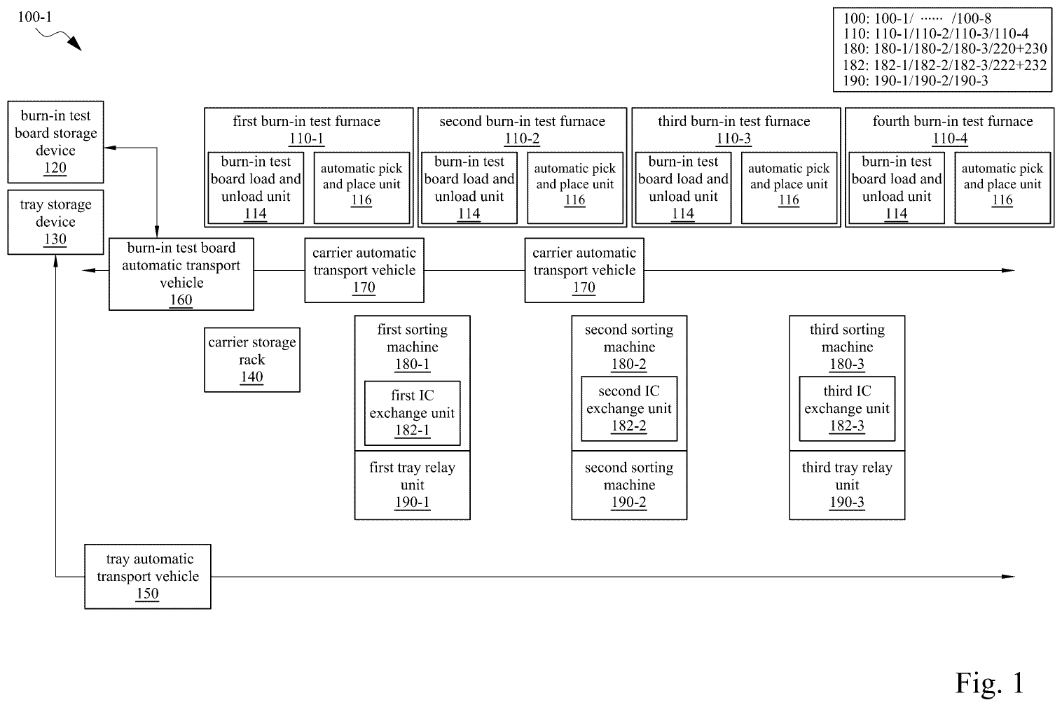

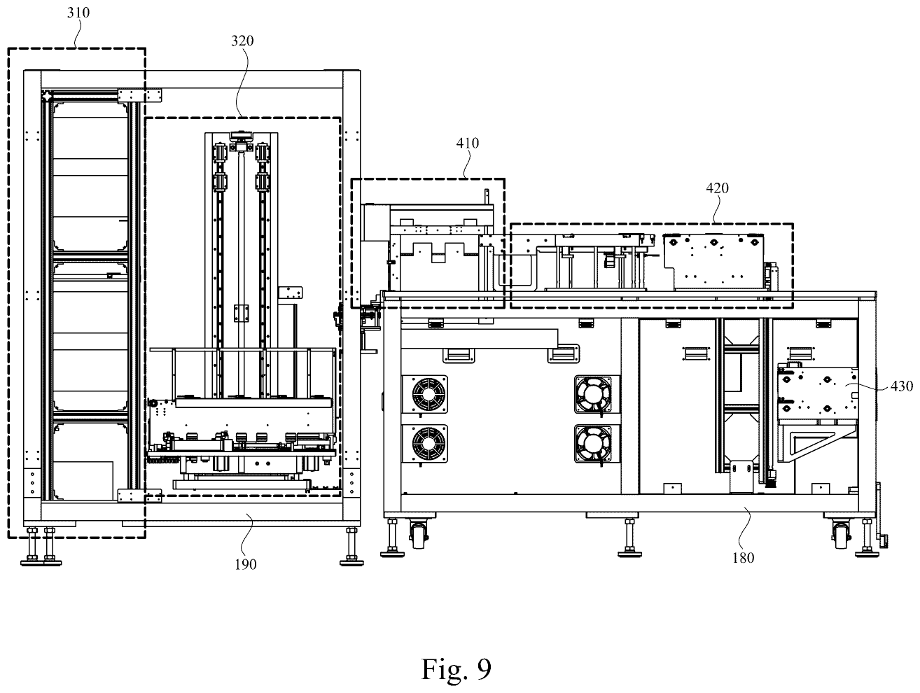

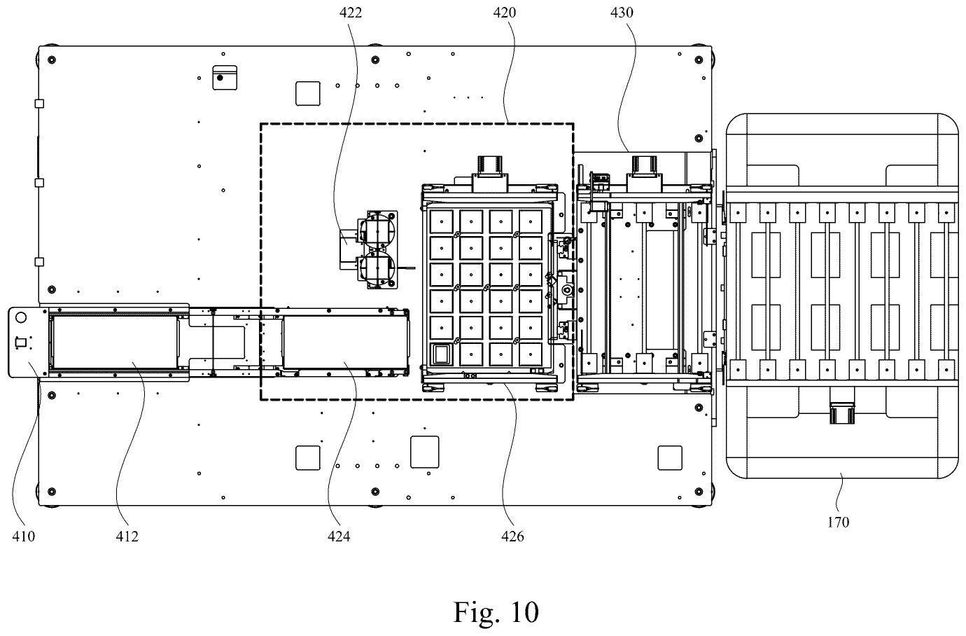

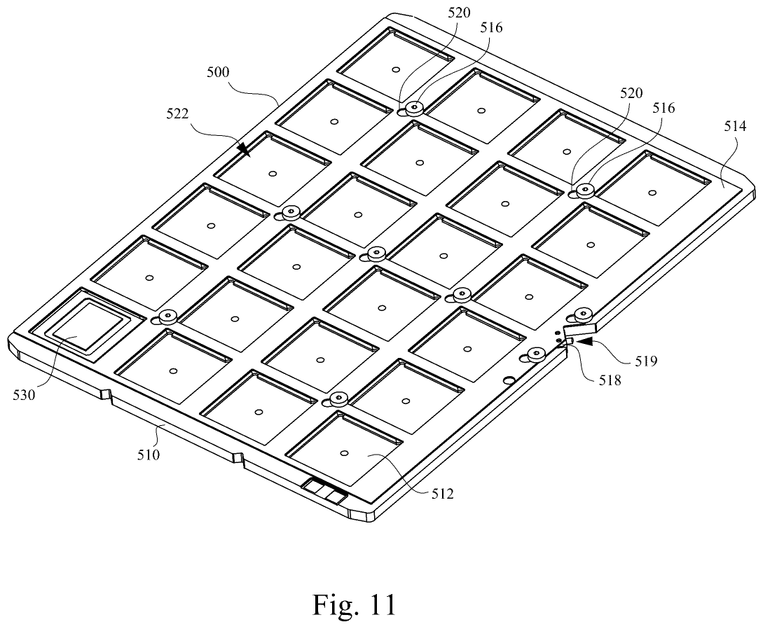

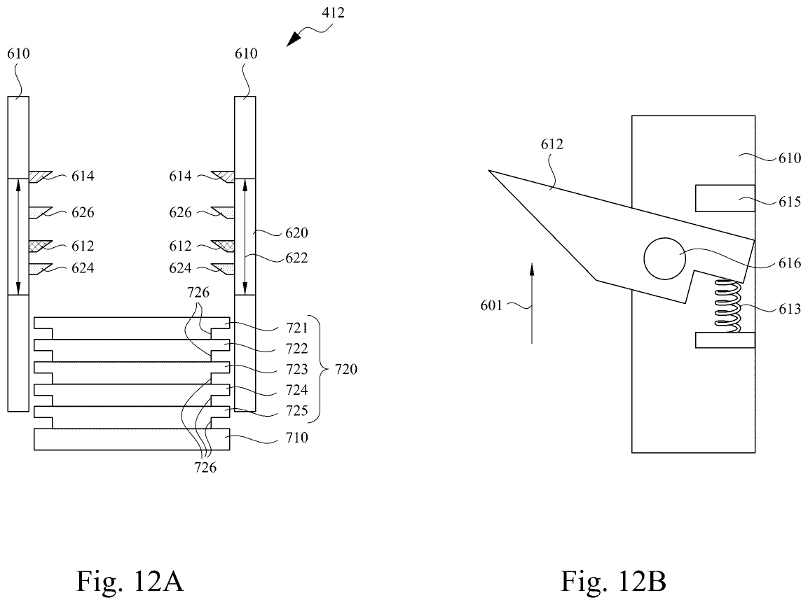

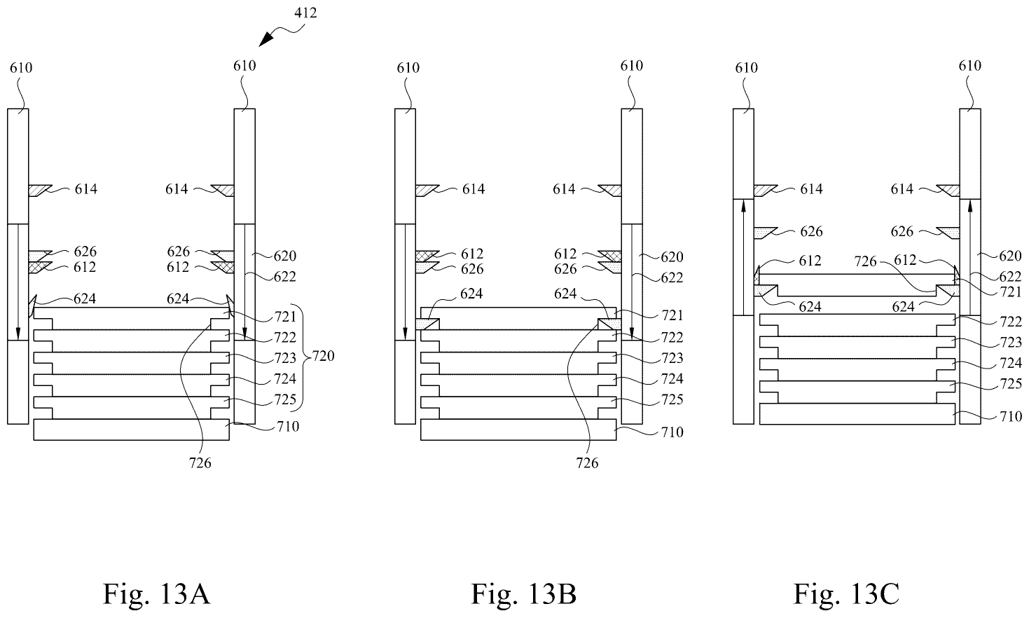

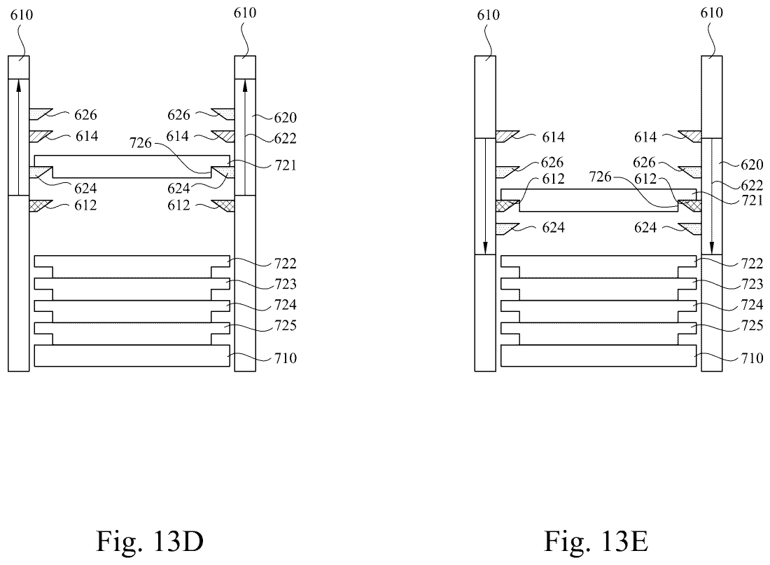

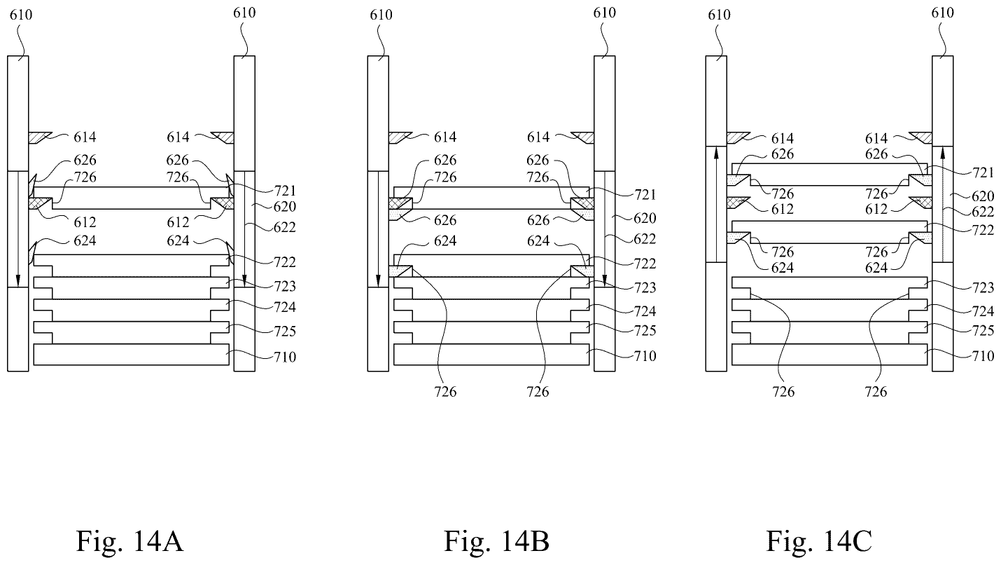

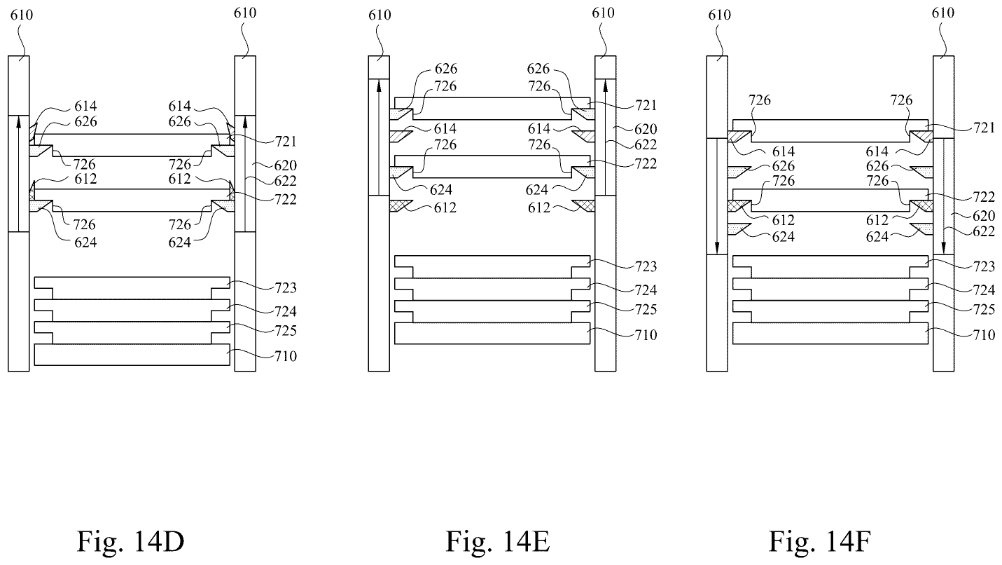

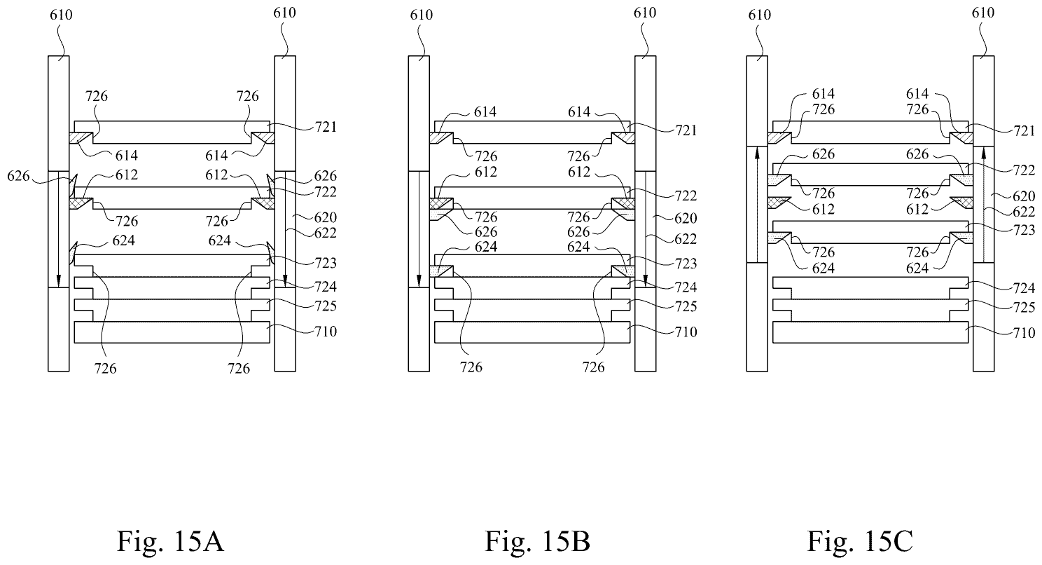

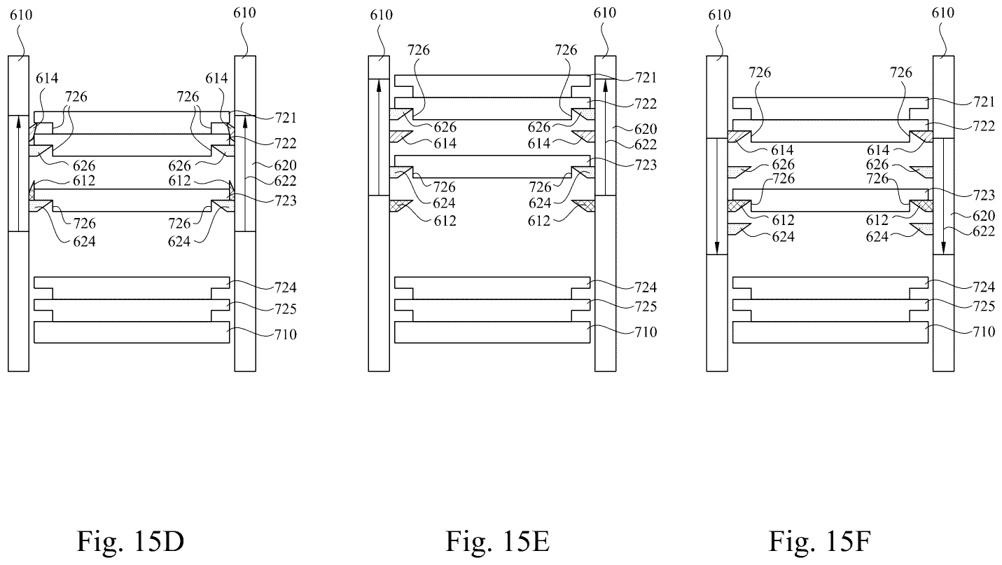

FIGS. 1-8 illustrate schematic views of the automated burn-in test system according to a plurality of embodiments of the present invention. FIG. 9 is a side view of a sorting machine and a tray relay unit of an automated burn-in test system according to one embodiment of the present invention. FIG. 10 is a top view of a sorting machine and a carrier automatic transport vehicle of an automated burn-in test system according to one embodiment of the present invention. FIG. 11 is a schematic perspective view of a carrier of the automated burn-in test system. FIG. 12A is a side view of a tray distribution module of the automated burn-in test system. FIG. 12B is an enlarged partial view of a rotatable rail of the tray distribution module. In addition, FIGS. 13A-13E are side views of the tray distribution module of the automated burn-in test system to explain a working process. FIGS. 14A-14F are side views of the tray distribution module of the automated burn-in test system to explain another working process. FIGS. 15A-15F are side views of the tray distribution module of the automated burn-in test system to explain further another working process.

Referring to FIG. 1, as shown in the drawing, the automated burn-in test system 100-1 includes a plurality of burn-in test furnaces 110, e.g. a first burn-in test furnace 110-1, a second burn-in test furnace 110-2, a third burn-in test furnace 110-3 and/or a fourth burn-in test furnace 110-4, a tray storage device 130 and a plurality of sorting machines 180, e.g. a first sorting machine 180-1, a second sorting machine 180-2 and/or a third sorting machine 180-3.

The tray storage device 130 is arranged on one side of the burn-in test furnaces 110 to store a plurality of trays, and a plurality of chips are accommodated on the trays. Therefore, the tray storage device 130 is utilized to store the chips and the trays to conveniently conduct the subsequent burn-in tests for chips.

The sorting machines 180 is arranged between the burn-in test furnaces 110 and the tray storage device 130, the sorting machines 180 may exchange the chips between the trays and the carriers. In some embodiments, the sorting machines 180 may move the chips on the trays to a plurality of carriers to transfer the chips to the burn-in test furnaces 110 to burn-in the chips so as to improve the quality thereof. In another embodiment, the sorting machines 180 may further classify the chips of the carriers to different trays according to the test results of the chips after the burn-in test is finished.

In some embodiments, each sorting machine 180 includes an IC exchange unit 182 to exchange the chips between the trays and the carriers. In some embodiments, the IC exchange unit 182 may move the chips on the trays to the carriers to transfer the chips to the burn-in test furnaces 110 and further perform the burn-in test so as to improve the quality of the chips. In another embodiment, the IC exchange unit 182 may further classify the chips of the carriers to different trays according to the test results of the chips after the burn-in test is finished.

In some embodiments, the first sorting machine 180-1 is equipped with a first IC exchange unit 182-1, a second sorting machine 180-2 is equipped with a second IC exchange unit 182-2, and the third sorting machine 180-3 is equipped with a third IC exchange unit 182-3.

In some embodiments, the automated burn-in test system 100-1 further includes a tray automatic transport vehicle 150 arranged between the tray storage device 130 and the sorting machines 180 to transfer the trays from the tray storage device 130 to the sorting machines 180.

In some embodiments, the automated burn-in test system 100-1 further includes a plurality of tray relay units 190, e.g. a first tray relay unit 190-1, a second tray relay unit 190-2 and/or a third tray relay unit 190-3 respectively arranged between the tray automatic transport vehicle 150 and the first sorting machine 180-1, the second sorting machine 180-2 and the third sorting machine 180-3. The tray relay units 190 are utilized to temporarily store the trays and provide the required trays for the sorting machines 180. The trays can be transported from the tray storage device 130 to the tray relay units 190 for temporary storage by the tray automatic transport vehicle 150 and then supplied to the sorting machine 180 by the tray relay device 190.

In some embodiments, the automated burn-in test system 100-1 further includes a carrier storage rack 140 and a carrier automatic transport vehicle 170. The carrier storage rack 140 is equipped adjacent to the burn-in test furnaces 110 and the sorting machines 180 to store the carriers for test. The carrier automatic transport vehicle 170 is arranged between the carrier storage rack 140, the sorting machines 180 and the burn-in test furnaces 110 to move the carriers between the carrier storage rack 140, the sorting machines 180 and the burn-in test furnaces 110.

In some embodiments, the automated burn-in test system 100-1 further includes a burn-in test board storage device 120 and a burn-in test board automatic transport vehicle 160. The burn-in test board storage device 120 is arranged adjacent to the burn-in test furnaces 110, or the burn-in test board storage device 120 and the burn-in test furnaces 110 may be disposed in different areas. The burn-in test board storage device 120 is utilized to store the burn-in test boards (BIBs). The burn-in test board automatic transport vehicle 160 is arranged between the burn-in test board storage device 120 and the burn-in test furnaces 110 to transfer the required burn-in test boards between the burn-in test board storage device 120 and the burn-in test furnaces 110.

In some embodiments, each burn-in test furnace 110 includes a burn-in test board load and unload unit 114 and an internal automatic pick and place unit 116. The burn-in test board load and unload unit 114 may dock with the burn-in test board automatic transport vehicle 160 to load the burn-in test boards for the burn-in test or unload the burn-in test boards after the burn-in test is finished. The internal automatic pick and place unit 116 may dock with the carrier automatic transport vehicle 170 to load or unload the chips of the carriers so as to load the chips to be tested into the burn-in test furnaces 110 to perform the burn-in test for the chips, and also move the chips to the carriers after the burn-in test is finished.

Therefore, the automated burn-in test system 100-1 may increase the exchange efficiency of the chips so as to increase the burn-in test efficiency, quickly provide the required chips for the burn-in test furnaces 110 and reduce the number of transports by automated transport vehicles through the cooperation of the tray storage device 130, the sorting machines 180, the tray relay units 190 and the tray automatic transport vehicle 150, the tray automatic transporter 150 transports the chips and trays from the tray storage device 130 and temporarily stores them in the tray relay units 190 to meet the needs of corresponding the sorting machine 180. The burn-in test furnaces 110 are equipped with a burn-in test board load and unload unit 114 and an internal automatic pick and place unit 116, both of which are integrated into the burn-in furnace and suitable for chip testing with a short burn-in cycle. The burn-in test board automatic transport vehicle 160 may be used in conjunction with the burn-in test board load and unload unit 114 to automatically transport, install and unload burn-in test boards so as to effectively improve the installation efficiency of the burn-in test boards and further improve the testing efficiency of the chips.

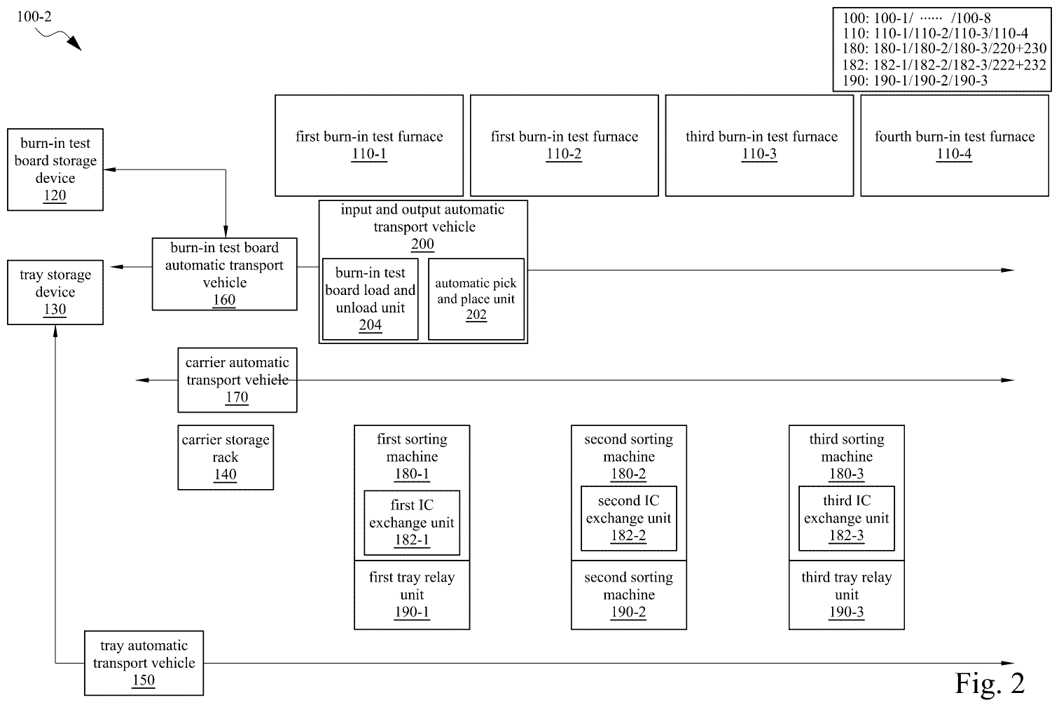

Further referring to FIG. 2, as shown in the drawing, compared with the automated burn-in test system 100-1, the automated burn-in test system 100-2 further includes an input and output automatic transport vehicle 200 arranged between the burn-in test board automatic transport vehicle 160, the burn-in test furnaces 110 and the carrier automatic transport vehicle 170 to load or unload the burn-in test boards and the chips of the carriers. It is worth noting that, in the exemplary embodiment, the burn-in test furnaces 110 do not integrate a burn-in test board load and unload unit 114 and an internal automatic pick and place unit 116. The input and output automatic transport vehicle 200 may move between the burn-in test board automatic transport vehicle 160, the burn-in test furnaces 110 and the carrier automatic transport vehicle 170 to reduce the required equipment cost.

In some embodiments, the input and output automatic transport vehicle 200 includes a burn-in test board load and unload unit 204 and an automatic pick and place unit 202. The burn-in test board load and unload unit 204 may dock with the burn-in test board automatic transport vehicle 160 to load or unload the burn-in test boards, and the automatic pick and place unit 202 may effectively dock with the carrier automatic transport vehicle 170 to load or unload the chips of the carriers to perform the burn-in test for the chips or move the chips to the carriers after the burn-in test is finished.

Therefore, the automated burn-in test system 100-2 may increase the exchange efficiency of the chips so as to increase the burn-in test efficiency, quickly provide the required chips for the burn-in test furnaces 110 and reduce the number of transports by automated transport vehicles through the cooperation among the tray storage device 130, the sorting machines 180, the tray relay units 190 and the tray automatic transport vehicle 150, the tray automatic transporter 150 transports the chips and trays from the tray storage device 130 and temporarily stores them in the tray relay units 190 to meet the needs of corresponding the sorting machine 180. In addition, by way of the burn-in test furnaces 110 and the input and output automatic transport vehicle 200 equipped with the burn-in test board load and unload unit 204 and the automatic pick and place unit 202, an one-to-many design is suitable for testing chips with a long burn-in cycle. In addition, the burn-in test board automatic transport vehicle 160 can be used in conjunction with the burn-in test board load and unload unit 204 to automatically transport, install and unload burn-in test boards so as to effectively improve the installation efficiency of loading and unloading burn-in test boards to further improve the efficiency of chip testing. Furthermore, the one-to-many design can significantly reduce equipment costs.

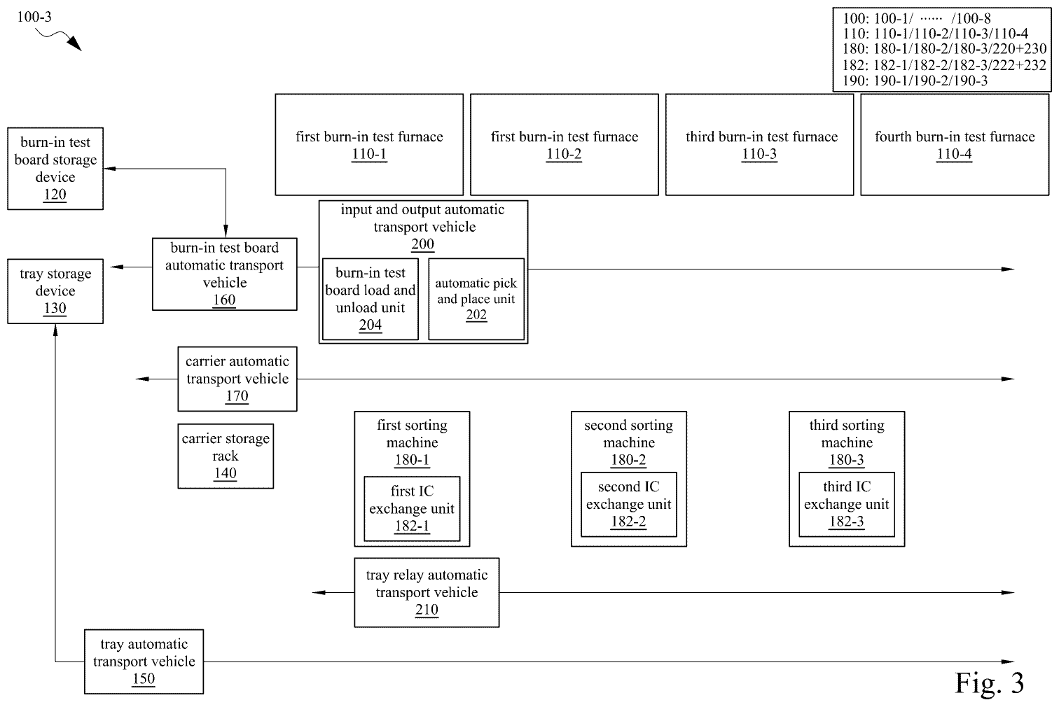

Further referring to FIG. 3, as shown in the drawing, compared with the automated burn-in test system 100-2, the automated burn-in test system 100-3 further includes a tray relay automatic transport vehicle 210 to replace a plurality of tray relay units 190, e.g. the first tray relay unit 190-1, the second tray relay unit 190-2 and the third tray relay unit 190-3 so as to utilize the tray relay automatic transport vehicle 210 moving between the sorting machines 180 and the tray automatic transport vehicle 150 to temporarily store the trays and the chips in the trays with one-to-many design.

Therefore, the automated burn-in test system 100-3 may utilize architecture between the tray storage device 130, the sorting machines 180, the tray relay automatic transport vehicle 210 and the tray automatic transport vehicle 150, the tray relay automatic transport vehicle 210 can correspond to multiple sorting machines 180, and the tray automatic transport vehicle 150 only needs to correspond to the needs of the tray relay automatic transport vehicle 210 to flexible adjust trays and chips in the tray relay automatic transport vehicle 210 and the sorting machines 180 so as to effectively reduce equipment costs. In addition, by way of the burn-in test furnaces 110, the input and output automatic transport vehicle 200 equipped with the burn-in test board load and unload unit 204 and the automatic pick and place unit 202, and the tray relay automatic transport vehicle 210, an one-to-many design is suitable for testing chips with a long burn-in cycle. In addition, the burn-in test board automatic transport vehicle 160 can be used in conjunction with the burn-in test board load and unload unit 204 to automatically transport, install and unload burn-in test boards so as to effectively improve the installation efficiency of loading and unloading burn-in test boards to further improve the efficiency of chip testing. Furthermore, the one-to-many design can significantly reduce equipment costs.

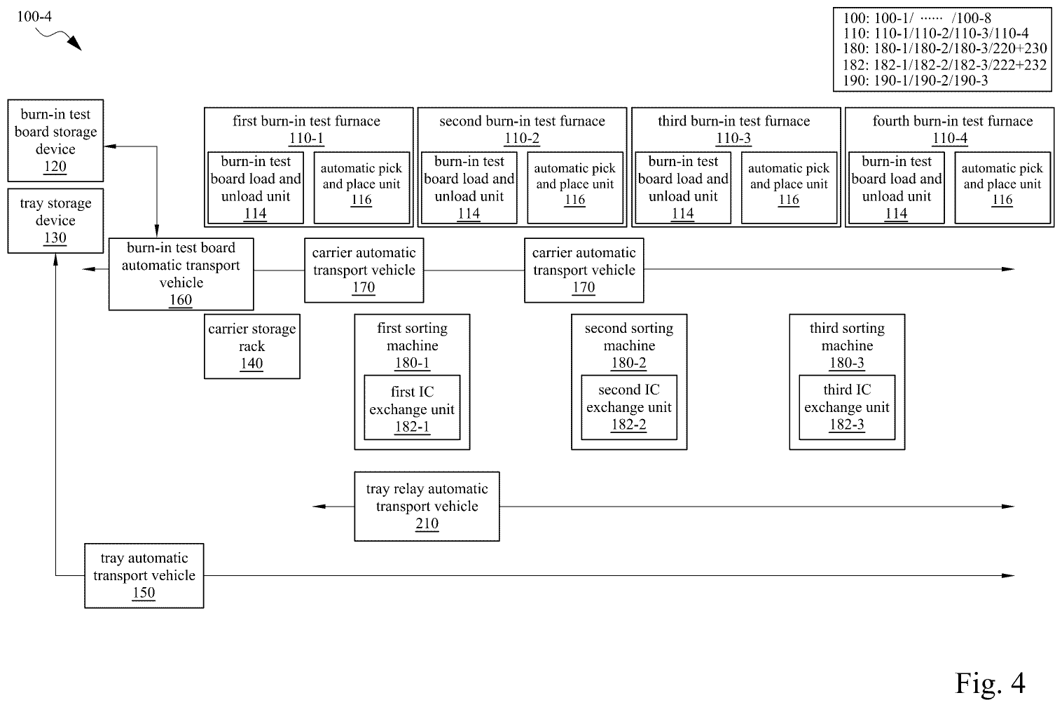

Further referring to FIG. 4, as shown in the drawing, compared with the automated burn-in test system 100-1, the automated burn-in test system 100-4 further includes a tray relay automatic transport vehicle 210 to replace a plurality of tray relay units 190, e.g. the first tray relay unit 190-1, the second tray relay unit 190-2 and the third tray relay unit 190-3 so as to utilize the tray relay automatic transport vehicle 210 moving between the sorting machines 180 and the tray automatic transport vehicle 150 to temporarily store the trays and the chips in the trays with one-to-many design.

Therefore, the automated burn-in test system 100-4 may utilize architecture between the tray storage device 130, the sorting machines 180, the tray relay automatic transport vehicle 210 and the tray automatic transport vehicle 150, the tray relay automatic transport vehicle 210 can correspond to multiple sorting machines 180, and the tray automatic transport vehicle 150 only needs to correspond to the needs of the tray relay automatic transport vehicle 210 to flexible adjust trays and chips in the tray relay automatic transport vehicle 210 and the sorting machines 180 so as to effectively reduce equipment costs. In addition, the burn-in test furnaces 110 are equipped with a burn-in test board load and unload unit 114 and an internal automatic pick and place unit 116, both of which are integrated into the burn-in furnace and suitable for chip testing with a short burn-in cycle. The burn-in test board automatic transport vehicle 160 may be used in conjunction with the burn-in test board load and unload unit 114 to automatically transport, install and unload burn-in test boards so as to effectively improve the installation efficiency of the burn-in test boards and further improve the testing efficiency of the chips. Furthermore, the one-to-many design can significantly reduce equipment costs.

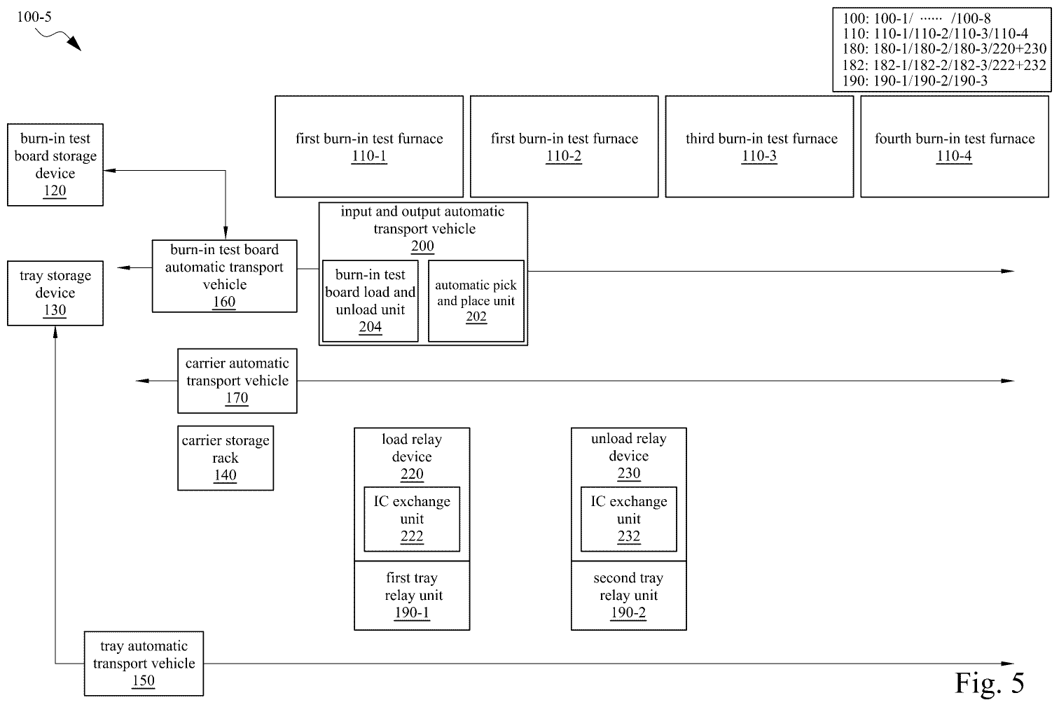

According to another aspect of the present invention, referring to FIG. 5, as shown in the drawing, compared with automated burn-in test system 100-2 of FIG. 2, the automated burn-in test system 100-5 further utilizes a load relay device 220 and an unload relay device 230 to replace a plurality of sorting machines 180, e.g. the first sorting machine 180-1, the second sorting machine 180-2 and the third sorting machine 180-3. The load relay device 220 is utilized to move the chips to the carriers, and the unload relay device 230 is utilized to move the chips to the trays. The load relay device 220 and the unload relay device 230 respectively include an IC exchange unit 222 and an IC exchange unit 232 to move the chips between the carriers and the trays.

In some embodiments, the automated burn-in test system 100-5 further includes a first tray relay unit 190-1 and a second tray relay unit 190-2. The first tray relay unit 190-1 is arranged between the load relay device 220 and the tray automatic transport vehicle 150 to temporarily store the trays and the chips, and the second tray relay unit 190-2 is arranged between the unload relay device 230 and the tray automatic transport vehicle 150 to temporarily store the trays and the chips.

Therefore, the automated burn-in test system 100-5 may utilize architecture between the tray storage device 130, the load relay device 220, the unload relay device 230, the first tray relay unit 190-1, the second tray relay unit 190-2 and the tray automatic transport vehicle 150, the first tray relay unit 190-1 and the second tray relay unit 190-2 correspond to the load relay device 220 and the unload relay device 230 respectively to provide individual exclusive supplies and the tray automatic transport vehicle 150 can supply the needs of the multiple tray relay units 190 to increase the exchange efficiency of the chips so as to quickly provide the required chips for the burn-in test furnaces 110 and reduce the number of transports by automated transport vehicles. In addition, by way of the burn-in test furnaces 110 and the input and output automatic transport vehicle 200 equipped with the burn-in test board load and unload unit 204 and the automatic pick and place unit 202, an one-to-many design is suitable for testing chips with a long burn-in cycle. In addition, the burn-in test board automatic transport vehicle 160 can be used in conjunction with the burn-in test board load and unload unit 204 to automatically transport, install and unload burn-in test boards so as to effectively improve the installation efficiency of loading and unloading burn-in test boards to further improve the efficiency of chip testing. Furthermore, the one-to-many design can significantly reduce equipment costs.

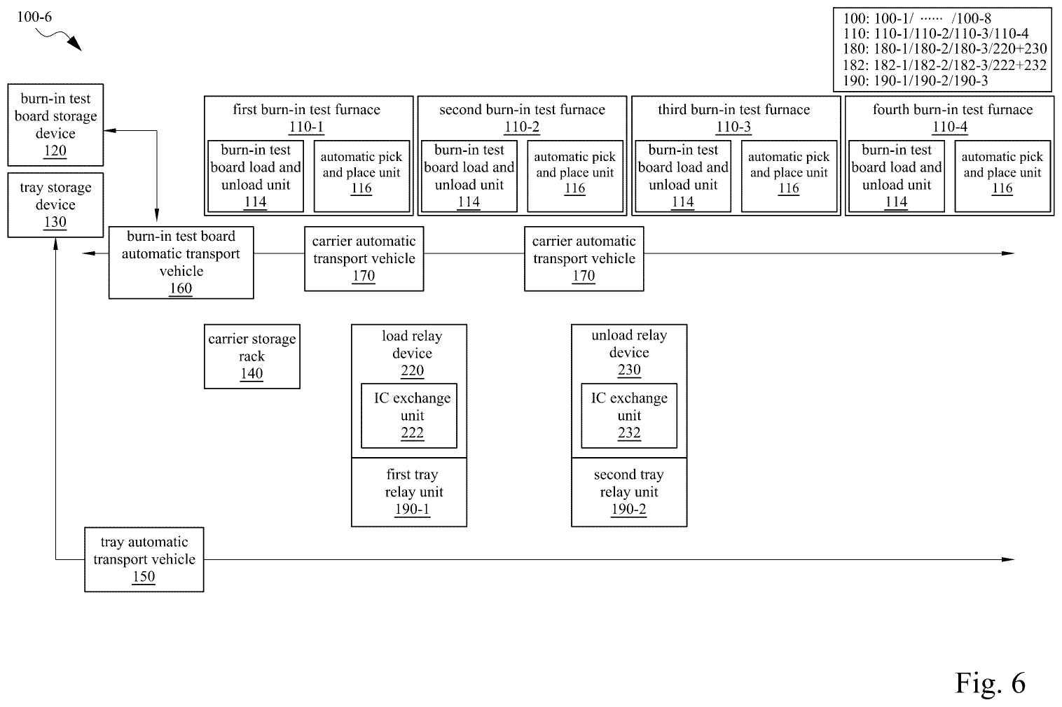

Referring to FIG. 6, as shown in the drawing, compared with the automated burn-in test system 100-1 of FIG. 1, the automated burn-in test system 100-6 utilizes a load relay device 220 and a unload relay device 230 to replace the plurality of sorting machines 180, e.g. the first sorting machine 180-1, the second sorting machine 180-2 and the third sorting machine 180-3. In addition, the load relay device 220 is utilized to move the chips to the carriers, and the unload relay device 230 is utilized to move the chips to the trays. In addition, the load relay device 220 and the unload relay device 230 respectively include an IC exchange unit 222 and an IC exchange unit 232 to move the chips between the carriers and the trays.

In some embodiments, the automated burn-in test system 100-6 further includes a first tray relay unit 190-1 and a second tray relay unit 190-2. The first tray relay unit 190-1 is equipped between the load relay device 220 and the tray automatic transport vehicle 150 to temporarily store the trays and the chips, and the second tray relay unit 190-2 is equipped between the unload relay device 230 and the tray automatic transport vehicle 150 to temporarily store the trays and the chips.

Therefore, by way of architecture of the tray storage device 130, the load relay device 220, the unload relay device 230, the first tray relay unit 190-1, the second tray relay unit 190-2 and the tray automatic transport vehicle 150, the first tray relay unit 190-1 and the second tray relay unit 190-2 correspond to the load relay device 220 and the unload relay device 230 respectively to provide individual exclusive supplies and the tray automatic transport vehicle 150 can supply the needs of the multiple tray relay units 190, the automated burn-in test system 100-6 may be utilized to simultaneously load and unload the chips of different lots at the same time to increase the exchange efficiency of the chips so as to quickly provide the required chips for the burn-in test furnaces 110 and reduce the number of transports by automated transport vehicles. In addition, the burn-in test furnaces 110 are equipped with a burn-in test board load and unload unit 114 and an internal automatic pick and place unit 116, which are suitable for chip testing with a short burn-in cycle. The burn-in test board automatic transport vehicle 160 may be used in conjunction with the burn-in test board load and unload unit 114 to automatically transport, install and unload burn-in test boards so as to effectively improve the installation efficiency of the burn-in test boards and further improve the testing efficiency of the chips.

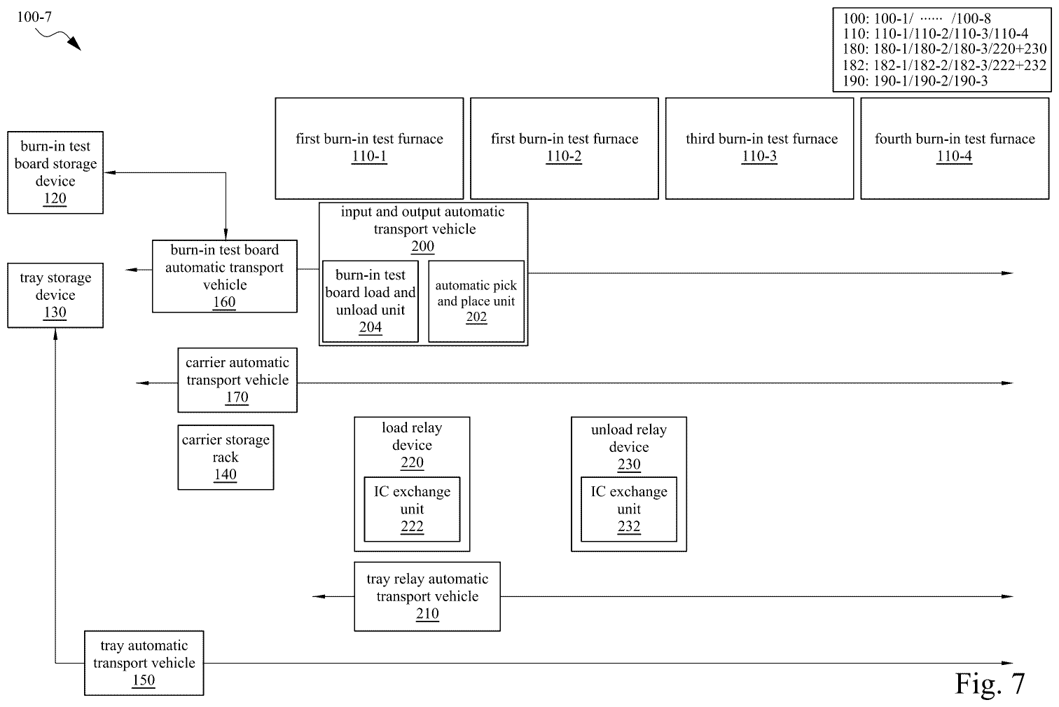

Referring to FIG. 7, as shown in the drawing, compared with the automated burn-in test system 100-6 of FIG. 6, the automated burn-in test system 100-7 further includes an input and output automatic transport vehicle 200 arranged between the burn-in test board automatic transport vehicle 160, the burn-in test furnaces 110 and the carrier automatic transport vehicle 170 to load or unload the burn-in test boards and the chips of the carriers. It is worth noting that, at the moment, the burn-in test furnaces 110 do not integrate the burn-in test board load and unload unit 114 and the internal automatic pick and place unit 116. The input and output automatic transport vehicle 200 may move between the burn-in test board automatic transport vehicle 160, the burn-in test furnaces 110 and the carrier automatic transport vehicle 170 to effectively reduce equipment costs.

In some embodiments, the input and output automatic transport vehicle 200 may include a burn-in test board load and unload unit 204 and an automatic pick and place unit 202. The burn-in test board load and unload unit 204 may dock with the burn-in test board automatic transport vehicle 160 to load or unload the burn-in test boards, and the automatic pick and place unit 202 may effectively dock with the carrier automatic transport vehicle 170 to load or unload the chips of the carriers so as to perform the burn-in test for the chips or move the chips to the carriers after the burn-in test is finished.

In addition, the automated burn-in test system 100-7 further includes a tray relay automatic transport vehicle 210 to replace a plurality of tray relay units 190, e.g. the first tray relay unit 190-1, the second tray relay unit 190-2 and the third tray relay unit 190-3 so as to utilize the tray relay automatic transport vehicle 210 moving between the load relay device 220, the unload relay device 230 and the tray automatic transport vehicle 150 to temporarily store the trays and the chips in the trays with one-to-many design.

Therefore, the automated burn-in test system 100-7 may utilize architecture between the tray storage device 130, the load relay device 220, the unload relay device 230, the tray relay automatic transport vehicle 210 and the tray automatic transport vehicle 150, the tray relay automatic transport vehicle 210 can be connected to the load relay device 220 and the unload relay device 230 according to the needs and provide transportation, and the tray automatic transport vehicle 150 can provide transportation for the tray relay automatic transport vehicle 210. The tray storage device 130, the load relay device 220 and the unload relay device 230 are transported in sections by the tray automatic transport vehicle 150 and the tray relay automatic transport vehicle 210 to flexible adjust the tray relay automatic transport vehicle 210, the load relay device 220 and the unload relay device 230 so as to effectively reduce equipment costs. In addition, by way of the burn-in test furnaces 110, the input and output automatic transport vehicle 200 equipped with the burn-in test board load and unload unit 204 and the automatic pick and place unit 202, and the tray relay automatic transport vehicle 210, an one-to-many design is suitable for testing chips with a long burn-in cycle. In addition, the burn-in test board automatic transport vehicle 160 can be used in conjunction with the burn-in test board load and unload unit 204 to automatically transport, install and unload burn-in test boards so as to effectively improve the installation efficiency of loading and unloading burn-in test boards to further improve the efficiency of chip testing. Furthermore, the one-to-many design can significantly reduce equipment costs.

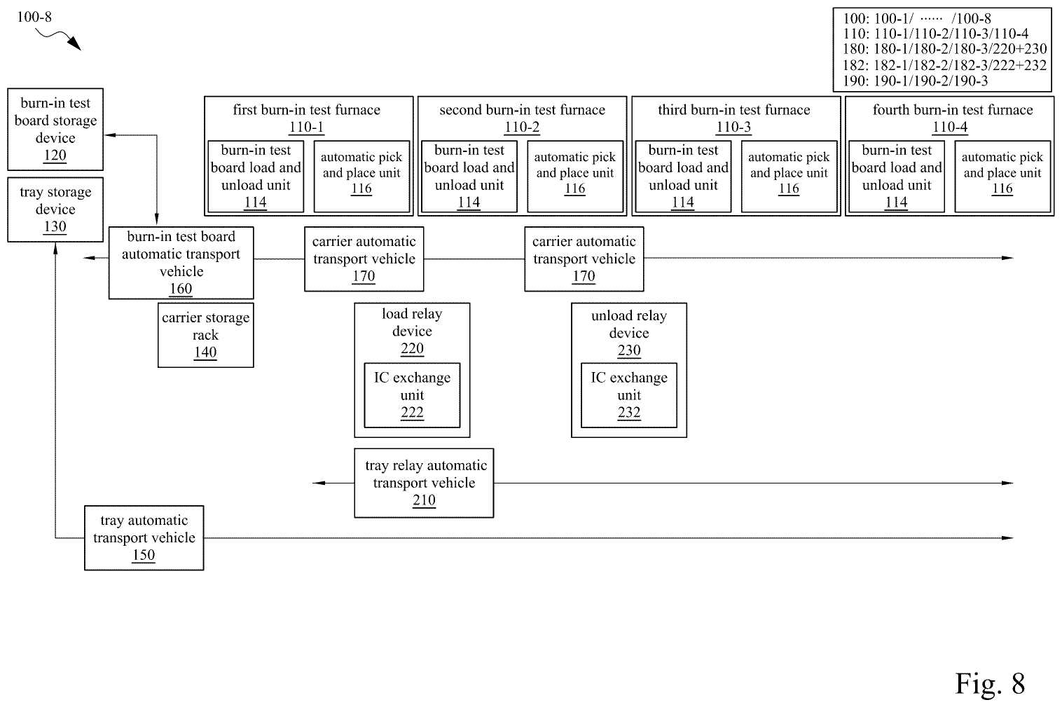

Further referring to FIG. 8, as shown in the drawing, compared with the automated burn-in test system 100-7 of FIG. 7, each burn-in test furnace 110 of the automated burn-in test system 100-8 further includes a burn-in test board load and unload unit 114 and an internal automatic pick and place unit 116, both of which are integrated into the burn-in furnace. The burn-in test board load and unload unit 114, which is built in, may dock with the burn-in test board automatic transport vehicle 160 to load the burn-in test boards for test the chips or unload the burn-in test boards after the chips tested. The internal automatic pick and place unit 116 may dock with the carrier automatic transport vehicle 170 to load or unload the chips of the carriers so as to perform the burn-in test for the chips in the burn-in test furnaces 110 or move the chips to the carriers after the burn-in test is finished.

Therefore, the automated burn-in test system 100-8 may utilize architecture between the tray storage device 130, the load relay device 220, the unload relay device 230, the tray relay automatic transport vehicle 210 and the tray automatic transport vehicle 150, the tray relay automatic transport vehicle 210 can be connected to the load relay device 220 and the unload relay device 230 according to the needs and provide transportation, and the tray automatic transport vehicle 150 can provide transportation for the tray relay automatic transport vehicle 210. The tray storage device 130, the load relay device 220 and the unload relay device 230 are transported in sections by the tray automatic transport vehicle 150 and the tray relay automatic transport vehicle 210 to flexible adjust the tray relay automatic transport vehicle 210, the load relay device 220 and the unload relay device 230 so as to effectively reduce equipment costs. In addition, because the burn-in test furnaces 110 are equipped with a burn-in test board load and unload unit 114 and an internal automatic pick and place unit 116, both of which are integrated into the burn-in furnace and suitable for chip testing with a short burn-in cycle. The burn-in test board automatic transport vehicle 160 may be used in conjunction with the burn-in test board load and unload unit 114 to automatically transport, install and unload burn-in test boards so as to effectively improve the installation efficiency of the burn-in test boards and further improve the testing efficiency of the chips.

In addition, referring to FIG. 9 and FIG. 10, as shown in the drawings, in some embodiments, the tray relay units 190 includes a tray storage unit 310 and a tray moving unit 320. The tray storage unit 310 is utilized to store the trays, and the tray moving unit 320 is arranged on one side of the tray storage unit 310 to move the trays into the tray storage unit 310 or remove the trays from the tray storage unit 310. In addition, the sorting machines 180 further include a tray distribution unit 410, an IC exchange unit 420 and a carrier storage unit 430. The IC exchange unit 420 is utilized to move the chips on the trays to the carriers and move the chips on the carriers to the trays, and the carrier storage unit 430 may utilized to temporarily store the carriers.

In some embodiments, the IC exchange unit 420 includes an IC rotating module 422, a tray locating device 424 and a carrier locating device 426. The tray locating device 424 is arranged on one side of the IC rotating module 422 to position the trays, and the carrier locating device 426 is arranged on another side of the IC rotating module 422 to position the carriers. In addition, the IC rotating module 422 may pick one chip on the trays in the tray locating device 424 and rotate the chip to a predetermined direction, and then place the chip in the carrier.

In some embodiments, the IC exchange unit 420 may include a visual module and a pick and place module. In some embodiments, the visual module may first identify the direction of the chips on the trays, and when the direction of the chips on the trays is different from a predetermined direction of the chips on the carriers, the pick and place module, e.g. a suction nozzle, may pick the chips on the trays to the IC rotating module 422, and the pick and place module may further place the chips to the carriers after the chip is rotated to the predetermined direction, without departing from the spirit and protection scope of the present invention.

In some embodiments, the visual module and the pick and place module may also be equipped in the IC rotating module 422, the visual module may first identify the direction of the chips on the trays, and when the direction of the chips on the trays is different from a predetermined direction of the chips on the carriers, the pick and place module, e.g. a suction nozzle, may pick the chips on the trays to the IC rotating module 422, and the pick and place module may further place the chips to the carriers after the chip is rotated to the predetermined direction, without departing from the spirit and protection scope of the present invention.

Referring to FIG. 11, the carriers 500 includes a base plate 510, a plurality of positioning units 516, a baffle 514, a pushing piece 518 and an elastic device 519. The base plate 510 includes a plurality of IC seats 512 thereon to support the chips 530, and the positioning units 516 are fixed on the base plate 510. The baffle 514 is movably installed on the base plate 510. In some embodiments, the baffle 514 may include a plurality of sliding slots 520 and a plurality of openings 522, the sliding slots 520 may be movably engaged with the positioning units 516, and the openings 522 are disposed corresponding to the IC seats 512. The pushing piece 518 is equipped on the base plate 510, and the pushing piece 518 is connected to the baffle 514. When the pushing piece 518 is pushed, the baffle 514 may move together with the pushing piece 518 to allow the openings 522 aligning with corresponding IC seats 512 to expose the chips 530 disposed on the IC seats 512. In addition, the elastic device 519 are connected between the pushing piece 518 and the base plate 510 to allow the baffle 514 returning to a predetermined position. At the predetermined position, the openings 522 of the baffle 514 are biased with the IC seats 512 to cover a partial area of the chips 530 supported on the IC seats 512 to fix the chips 530 on the IC seats 512 so as to safely and conveniently move the carriers 500 and the chips stored on the carriers 500.

Further referring to FIG. 12A and FIG. 12B, the tray distribution module 412 of the automated burn-in test system 100 is illustrated in FIG. 12A, and FIG. 12B is a partial enlarged view thereof. As shown in the drawings, the tray distribution unit 410 includes a tray distribution module 412, and the tray distribution module 412 includes a supporting wall 610, a rotatable rail 612, a rotatable supporting device 614 and a tray picking device 620. The rotatable rail 612 is rotatably installed on the supporting wall 610, and the rotatable supporting device 614 may also be rotatably installed on the supporting wall 610 and located above the rotatable rail 612. The tray picking device 620 is movably installed on the supporting wall 610.

In some embodiments, the tray distribution module 412 further includes a shaft 616, an elastic device 613 and a stopping block 615. The shaft 616 is fixed on the supporting wall 610, the rotatable rail 612 is rotatably mounted on the shaft 616, and the elastic device 613 is connected between the rotatable rail 612 and the supporting wall 610. In addition, the stopping block 615 is fixed on the supporting wall 610 to limit the rotational angle of the rotatable rail 612 and support the trays. The rotatable rail 612 may rotate upwardly along the tray moving direction 601 to allow the trays passing through and support the trays after the trays passed therethrough. In addition, the shaft 616, the elastic device 613 and the stopping block 615 may cooperate with a rotatable supporting device 614, so that the rotatable supporting device 614 may also rotate upward along the tray moving direction 601 to allow the trays passing through and support the trays after the trays passed therethrough.

In some embodiments, the tray picking device 620 includes a moving unit 622, a first rotatable protrusion 624 and a second rotatable protrusion 626. The moving unit 622 is movably installed on the supporting wall 610 to allow the tray picking device 620 moving along the supporting wall 610 up and down. In addition, the first rotatable protrusion 624 may be rotatably installed on the moving unit 622, the second rotatable protrusion 626 may be rotatably installed on the moving unit 622, and the second rotatable protrusion 626 is preferably located above the first rotatable protrusion 624. In some embodiments, the shaft 616, the elastic device 613 and the stopping block 615 may cooperate with the first rotatable protrusion 624 and the second rotatable protrusion 626, so that the first rotatable protrusion 624 and the second rotatable protrusion 626 may also rotate upward on the moving unit 622 to allow the trays passing through and support the trays after the trays passed therethrough.

In some embodiments, the tray distribution module 412 further includes a lifting device 710 installed under the tray picking device 620 to lift the trays 720 up and down, e.g. a first tray 721, a second tray 722, a third tray 723, a fourth tray 724 and/or a fifth tray 725, supported thereon.

Further refer to FIG. 13A to FIG. 15F, the working flow diagrams of the tray distribution module 412 for taking trays from a plurality of trays are illustrated. First referring to FIG. 13A to FIG. 13E, the working flow diagrams of taking out the topmost first tray 721 of the trays 720 from the trays 720 are illustrated.

As shown in FIG. 13A, the moving unit 622 of the tray picking device 620 first moves downwardly, and the first rotatable protrusion 624 located on the moving unit 622 may rotate upwardly because the reaction force generated by the first rotatable protrusion 624 contacting the first tray 721 so as to allow the first tray 721 passing through the first rotatable protrusion 624. Further referring to FIG. 13B, the first rotatable protrusion 624 is returned to the horizontal position and supports the first tray 721 at the indentation portion 726 of the first tray 721.

Subsequently referring to FIG. 13C, because the moving unit 622 of the tray picking device 620 moves upwardly, the first tray 721 on the first rotatable protrusion 624 may move upwardly together with the first rotatable protrusion 624 and pushes the rotatable rail 612 to rotate upwardly and the moving unit 622 may continuously move upwardly.

It is worth noting that because the first tray 721 moves together with the first rotatable protrusion 624, the lifting device 710 may further move the trays 720 upwardly so that the second tray 722 may locate at a previous positon of the first tray 721 to be conveniently taken out by the tray picking device 620 in next process, but the present invention is not limited thereto. The lifting device 710 may further move the trays 720 upward to place the second tray 722 located at the previous positon of the first tray 721 just before the next process, without departing from the spirit and protection scope of the present invention.

Referring to FIG. 13D, the moving unit 622 continuously moves upward to allow the first tray 721 on the first rotatable protrusion 624 higher than the rotatable rail 612, and the rotatable rail 612 returning to the horizontal supporting position.

Refer FIG. 13E, the moving unit 622 moves downward so that the first rotatable protrusion 624 continuously moves downward to allow the first rotatable protrusion 624 lower than the rotatable rail 612, and the first tray 721 contacts the rotatable rail 612 and supports on the rotatable rail 612. Therefore, the first tray 721 of the trays 720 may be moved to the rotatable rail 612, the first tray 721 may be transferred to the tray locating device 424 by a transfer module (not shown) adjacent to the tray distribution module 412 to pick and place the chips until the chips are completely picked from or placed on the first tray 721, the first tray 721 may be returned to the rotatable rail 612 by the transfer module (not shown) to perform a subsequent process.

Further referring to FIG. 14A to FIG. 14F, working flow diagrams of taking a second tray 722 from the trays 720 are illustrated.

As shown in the FIG. 14A, a moving unit 622 of the tray picking device 620 is first moved downward, and the first rotatable protrusion 624 may rotate upwardly because the reaction force generated by the first rotatable protrusion 624 contacting the second tray 722 so as to allow the second tray 722 passing through the first rotatable protrusion 624. At the time, the first tray 721 continuously support on the rotatable rail 612.

At the time, the second rotatable protrusion 626 continuously moves downward and contacts the first tray 721 so as to generate a reaction force to rotate upward and the second rotatable protrusion 626 may pass through the first tray 721 and then return to the horizontal position. In addition, the first rotatable protrusion 624 may contact the second tray 722 so as to generate a reaction force to rotate upward and the first rotatable protrusion 624 may enter into the indentation portion 726 of the second tray 722 and return to the horizontal position, referring to FIG. 14B. In the FIG. 14A, the second rotatable protrusion 626 may rotate before the first rotatable protrusion 624, or the second rotatable protrusion 626 may simultaneously rotate with the first rotatable protrusion 624, without departing from the spirit and protection scope of the present invention.

Referring to FIG. 14B, the first rotatable protrusion 624 is rotated back to the horizontal position through the indentation portion 726 of the second tray 722 to support the second tray 722.

In addition, referring to FIG. 14C, because the moving unit 622 of the tray picking device 620 moves upward, the second tray 722 on the first rotatable protrusion 624 may moves upward together with the first rotatable protrusion 624, and the first tray 721 on the rotatable rail 612 may be moved upward together with the second rotatable protrusion 626 on the tray picking device 620.

Referring to FIG. 14D, the moving unit 622 continuously moves upward to push the rotatable rail 612 by the second tray 722 on the first rotatable protrusion 624 so as to rotate the rotatable rail 612 upward, and the first tray 721 on the second rotatable protrusion 626 may simultaneously push and rotate the rotatable supporting device 614.

Referring to FIG. 14E, the moving unit 622 continuously moves upward to allow the second tray 722 on the first rotatable protrusion 624 higher than the rotatable rail 612 and the rotatable rail 612 returning to the original horizontal position, and at the same time, allow the first tray 721 on the second rotatable protrusion 626 higher than the rotatable supporting device 614 and the rotatable supporting device 614 returning to the original horizontal position.

It is worth noting that, after the second tray 722 moves upward together with the first rotatable protrusion 624 and the first tray 721 moves upward together with the second rotatable protrusion 626, the lifting device 710 may further move the trays 720 upward to allow the third tray 723 positioning at the previous position of the second tray 722 so as to be conveniently taken out by the tray picking device 620 in next process, but the present invention is not limited thereto. The lifting device 710 may further move the trays 720 upward just before the next process to conveniently take out the tray, without departing from the spirit and protection scope of the present invention.

Referring to FIG. 14F, the moving unit 622 moves downward to allow the second tray 722 on the first rotatable protrusion 624 to be supported on the rotatable rail 612, and at the same time, the first tray 721 on the second rotatable protrusion 626 to be supported on the rotatable supporting device 614. Therefore, the second tray 722 may further be taken out from the trays 720.

Referring to FIG. 15A to FIG. 15F, the working flow diagrams for further taking out the third tray 723 from the trays 720 are illustrated.

As shown in the drawings, the moving unit 622 of the tray picking device 620 may move downward again to take out the third tray 723, the processes are similar to the processes as shown in FIG. 14A to FIG. 14F. In addition, the third tray 723 is placed on the rotatable rail 612, and in the moment, the second tray 722 may push the first tray 721 upward to allow the second tray 722 and the first tray 721 are stacked together on the rotatable supporting device 614, but the present invention is not limited thereto. The tray distribution module 412 may repeat the processes until all of the trays 720 are completely taken out.

Accordingly, the automated burn-in test system disclosed in the present invention may utilize the tray storage device, the sorting machines, the tray relay units and the tray automatic transport vehicle to effectively increase the exchange efficiency of the chips and the burn-in test efficiency so as to quickly provide the required chips for the burn-in test furnaces and reduce the number of transports by automated transport vehicles. In addition, the burn-in test furnaces may be equipped with the burn-in test board load and unload unit and the internal automatic pick and place unit, both of which are integrated into the burn-in furnace and suitable for chip testing with a short burn-in cycle. In addition, the burn-in test board automatic transport vehicle may be used in conjunction with the burn-in test board load and unload unit to automatically transport, install and unload burn-in test boards so as to effectively improve the installation efficiency of the burn-in test boards and further improve the testing efficiency of the chips. Furthermore, because the input and output automatic transport vehicle is equipped with the burn-in test board load and unload unit and the automatic pick and place unit, an one-to-many design is suitable for testing chips with a long burn-in cycle. In addition, the tray relay automatic transport vehicle and the tray automatic transport vehicle may further flexible adjust the tray relay automatic transport vehicle and the chips on the trays in the sorting machines so as to effectively reduce equipment costs. Furthermore, by way of the load relay device, the unload relay device, the tray relay units and the tray automatic transport vehicle, the automated burn-in test system may effectively increase the exchange efficiency of the chips so as to quickly provide the required chips for the burn-in test furnaces and reduce the number of transports by automated transport vehicles to further improve the quality of the chips.

Although the present disclosure has been disclosed above in terms of implementation, it is not intended to limit the present disclosure. Any person with ordinary knowledge in the field may make various variations and modifications without departing from the spirit and scope of the disclosure. Therefore, the spirit and scope of the appended claims should not be limited to the description of the embodiments contained herein.

What is claimed is:

1. An automated burn-in test system, comprising:
a plurality of burn-in test furnaces;
a tray storage device arranged on one side of the burn-in test furnaces to accommodate a plurality of trays for storing a plurality of chips; and
a plurality of sorting machines arranged between the burn-in test furnaces and the tray storage device to exchange the chips between the trays and a plurality of carriers.

2. The automated burn-in test system of claim 1, wherein each of the sorting machines comprises:
an IC exchange unit to exchange the chips between the trays and the carriers.

3. The automated burn-in test system of claim 2, further comprising:
a tray automatic transport vehicle arranged between the tray storage device and the sorting machines to transfer the trays from the tray storage device to the sorting machines.

4. The automated burn-in test system of claim 3, further comprising:
a tray relay unit equipped between the sorting machines and the tray automatic transport vehicle to temporarily store the trays.

5. The automated burn-in test system of claim 4, wherein the tray relay unit is a tray relay automatic transport vehicle to move between the sorting machines and the tray automatic transport vehicle and temporarily store the trays.

6. The automated burn-in test system of claim 3, further comprising:
a carrier storage rack arranged adjacent to the burn-in test furnaces and the sorting machines to store the carriers.

7. The automated burn-in test system of claim 6, further comprising:
a carrier automatic transport vehicle arranged between the carrier storage rack, the sorting machines and the burn-in test furnaces to move the carriers in the carrier storage rack, the sorting machines and the burn-in test furnaces.

8. The automated burn-in test system of claim 7, further comprising:
a burn-in test board storage device to store a plurality of burn-in test boards.

9. The automated burn-in test system of claim 8, further comprising:
a burn-in test board automatic transport vehicle arranged between the burn-in test board storage device and the burn-in test furnaces to transfer the burn-in test boards between the burn-in test board storage device and the burn-in test furnaces.

10. The automated burn-in test system of claim 9, wherein each of the burn-in test furnaces comprises:
a burn-in test board load and unload unit to dock with the burn-in test board automatic transport vehicle for loading or unloading the burn-in test boards.

11. The automated burn-in test system of claim 10, wherein each of the burn-in test furnaces further comprises:
an automatic pick and place unit to dock with the carrier automatic transport vehicle to load or unload the chips of the carriers to burn-in the chips or move the chips to the carriers after a burn-in test is finished.

12. The automated burn-in test system of claim 9, further comprising:
an input and output automatic transport vehicle arranged between the burn-in test board automatic transport vehicle, the burn-in test furnaces and the carrier automatic transport vehicle to load and unload the burn-in test boards and the chips of the carriers.

13. The automated burn-in test system of claim 12, wherein the input and output automatic transport vehicle comprises:
a burn-in test board load and unload unit to dock with the burn-in test board automatic transport vehicle to load or unload the burn-in test boards.

14. The automated burn-in test system of claim 13, wherein the input and output automatic transport vehicle further comprises:
an automatic pick and place unit to dock with the carrier automatic transport vehicle to load or unload the chips of the carriers to burn-in the chips or move the chips to the carriers after a burn-in test is finished.

15. The automated burn-in test system of claim 14, further comprising:
a tray relay automatic transport vehicle equipped between the sorting machines and the tray automatic transport vehicle to move between the sorting machines and the tray automatic transport vehicle and temporarily store the trays.

16. The automated burn-in test system of claim 3, wherein the sorting machines comprise:
a load relay device to move the chips to the carriers; and
an unload relay device to move the chips to the trays.

17. The automated burn-in test system of claim 16, wherein the load relay device and the unload relay device respectively comprises an IC exchange unit to move the chips between the carriers and the trays.

18. The automated burn-in test system of claim 17, further comprising:
a first tray relay unit equipped between the load relay device and the tray automatic transport vehicle to temporarily store the trays; and
a second tray relay unit equipped between the unload relay device and the tray automatic transport vehicle to temporarily store the trays.

19. The automated burn-in test system of claim 17, further comprising:
a tray relay automatic transport vehicle equipped between the load relay device, the unload relay device and the tray automatic transport vehicle to move between the load relay device, the unload relay device and the tray automatic transport vehicle and temporarily store the trays.

20. The automated burn-in test system of claim 19, wherein each of the burn-in test furnaces comprises:
a burn-in test board load and unload unit to dock with a burn-in test board automatic transport vehicle to load or unload a plurality of burn-in test boards.

21. The automated burn-in test system of claim 20, wherein each of the burn-in test further furnaces comprises:
an automatic pick and place unit to dock with a carrier automatic transport vehicle to load or unload the chips of the carriers to burn-in the chips or move the chips to the carriers after a burn-in test is finished.

22. The automated burn-in test system of claim 19, further comprising:
an input and output automatic transport vehicle arranged between a burn-in test board automatic transport vehicle, the burn-in test furnaces and a carrier automatic transport vehicle to load or unload a plurality of burn-in test boards and the chips of the carriers.

23. The automated burn-in test system of claim 22, wherein the input and output automatic transport vehicle comprises:
a burn-in test board load and unload unit to dock with the burn-in test board automatic transport vehicle to load or unload the burn-in test boards.

24. The automated burn-in test system of claim 23, wherein the input and output automatic transport vehicle further comprises:
an automatic pick and place unit to dock with the carrier automatic transport vehicle to load or unload the chips of the carriers to burn-in the chips or move the chips to the carriers after a burn-in test is finished.

25. The automated burn-in test system of claim 4, wherein the tray relay unit comprises:
a tray storage unit to store the trays; and
a tray moving unit arranged on one side of the tray storage unit to move the trays into or remove the trays from the tray storage unit.

26. The automated burn-in test system of claim 1, wherein each of the sorting machines comprises:
a tray distribution unit;
an IC exchange unit to exchange the chips between the trays and the carriers; and
a carrier storage unit to temporarily store the carriers.

27. The automated burn-in test system of claim 26, wherein the IC exchange unit comprises:
an IC rotating module;
a tray locating device arranged on one side of the IC rotating module to position a tray; and
a carrier locating device arranged on another side of the IC rotating module to position a carrier, wherein when directions of the chips of the tray are not correct, the IC exchange unit picks one of the chips to the IC rotating module and the IC rotating module rotates the one of the chips to a predetermined direction, and then the IC exchange unit picks the one of the chips to the carriers.

28. The automated burn-in test system of claim 26, wherein the tray distribution unit comprises a tray distribution module, and the tray distribution module comprises:
a supporting wall;
a rotatable rail rotatably mounted on the supporting wall;
a rotatable supporting device rotatably mounted on the supporting wall and located above the rotatable rail; and
a tray picking device movably mounted on the supporting wall.

29. The automated burn-in test system of claim 28, wherein the tray distribution module further comprises:
a shaft fixed on the supporting wall, wherein the rotatable rail is rotatably mounted on the shaft;
an elastic device connected between the rotatable rail and the supporting wall; and
a stopping block fixed on the supporting wall to limit a rotational angle of the rotatable rail.

30. The automated burn-in test system of claim 29, wherein the tray picking device comprises:
a moving unit movably installed on the supporting wall;
a first rotatable protrusion rotatably installed on the moving unit; and
a second rotatable protrusion rotatably installed on the moving unit, and located above the first rotatable protrusion.

31. The automated burn-in test system of claim 30, wherein the tray distribution module further comprises:
a lifting device installed under the tray picking device to lift the trays.

32. The automated burn-in test system of claim 1, wherein each of the carriers comprises:
a base plate comprising a plurality of IC seats to support a plurality of chips;
a plurality of positioning units fixed on the base plate;
a baffle installed on the base plate, the baffle comprises a plurality of sliding slots and a plurality of openings, the sliding slots movably coupled to the positioning units, and the openings are disposed corresponding to the IC seats;
a pushing piece disposed on the base plate to move the baffle to expose the chips on the IC seats; and
an elastic device connected between the pushing piece and the base plate to reset the baffle so as to cover a portion area of the chips on the IC seats to fix the chips on the IC seats.
